(19) United States
(12) Patent Application Publication
(10) Pub. No.: US 2011/0187472 A1
(43) Pub. Date: Aug. 4, 2011

(54) PIEZOELECTRIC VIBRATING REED, PIEZOELECTRIC VIBRATOR, METHOD FOR MANUFACTURING PIEZOELECTRIC VIBRATOR, OSCILLATOR, ELECTRONIC APPARATUS, AND RADIO-CONTROLLED TIMEPIECE

(76) Inventor: Junya Fukuda, Chiba-shi (JP)

(21) Appl. No.: 13/018,930

(22) Filed: Feb. 1, 2011

(30) Foreign Application Priority Data
Feb. 3, 2010 (JP) 2010-022405

(51) Int. Cl. H03B 5/32; H01L 41/053; H01L 41/22

(52) U.S. Cl. 331/158; 310/348; 29/25.35

(57) ABSTRACT

There are provided a piezoelectric vibrating reed capable of securing a stable bonding strength between a bump and the piezoelectric vibrating reed, a piezoelectric vibrator having the piezoelectric vibrating reed, a method for manufacturing the piezoelectric vibrator, and an oscillator, an electronic apparatus, and a radio-controlled timepiece each having the piezoelectric vibrator. A piezoelectric vibrating reed includes: a vibrating portion; a base portion adjacent to the vibrating portion; excitation electrodes formed in the vibrating portion; mount electrodes formed in the base portion; and extraction electrodes for electrically connecting the excitation electrodes and the mount electrodes to each other. A bonding film made of gold is formed on the surfaces of the mount electrodes, and the bonding film is formed to a thickness such that, when the bonding film is ultrasonically bonded to a bump made of gold, mutual diffusion occurs over approximately the entire area in the thickness direction of the bonding film.

### RELATED APPLICATIONS

This application claims priority under 35 U.S.C. §119 to Japanese Patent Application No. 2010-022405 filed on Feb. 3, 2010, the entire content of which is hereby incorporated by reference.

### BACKGROUND OF THE INVENTION

1. Field of the Invention

The present invention relates to a piezoelectric vibrating reed, a piezoelectric vibrator, a method for manufacturing a piezoelectric vibrator, an oscillator, an electronic apparatus, and a radio-controlled timepiece.

2. Description of the Related Art

In the related art, a piezoelectric vibrator in which a pair of substrates is bonded together, and a piezoelectric vibrating reed is sealed in a cavity formed between the substrates is known. A piezoelectric vibrator is used in cellular phones and portable information terminals as the time source, the timing source of a control signal, a reference signal source, and the like. Various types of piezoelectric vibrators are known, and one example thereof is a surface mounted device-type piezoelectric vibrator.

As the surface mounted device-type piezoelectric vibrator, a two-layered piezoelectric vibrator in which a base substrate and a lid substrate are directly bonded together, and a piezoelectric vibrating reed is accommodated in a cavity formed between both substrates is known. The two-layered piezoelectric vibrator is ideally used as it is superior in achieving a thin profile. As an example of the two-layered piezoelectric vibrator, a piezoelectric vibrator is known in which a mount electrode of a piezoelectric vibrating reed and an outer electrode formed on a base substrate are electrically connected using a conductive member (penetration electrode) which is formed so as to penetrate through the base substrate.

Specifically, the penetration electrode is electrically connected to the outer electrode on the outer side of the base substrate, and the penetration electrode is electrically connected to a lead-out electrode on a cavity side of the base substrate. The lead-out electrode is formed on the surface of the base substrate. Moreover, a bump made of a metallic material is provided between the lead-out electrode and the mount electrode, and the lead-out electrode is ultrasonically bonded to the bump, and the bump is ultrasonically bonded to the mount electrode.

A technique of ultrasonically bonding the lead-out electrode and the mount electrode to each other using a gold film which is formed on the surfaces of the lead-out electrode and mount electrode bonded to the bump which is made of gold is disclosed, for example, in JP-A-11-266135 and JP-A-2001-102891.

However, in the above-described piezoelectric vibrator in which ultrasonic bonding is performed, the bonding strength between the bump and the piezoelectric vibrating reed (the mount electrode) is likely to show variations. Thus, it is difficult to maintain a stable bonding strength.

Therefore, in order to secure a bonding strength between the bump and the piezoelectric vibrating reed, a method of forming a plurality of bumps in one bonding place to perform ultrasonic bonding may be considered. However, this method has a problem in that production efficiency decreases.

### SUMMARY OF THE INVENTION

The invention has been made in view of the above problems. An object of the present invention is to provide a piezoelectric vibrating reed capable of securing a stable bonding strength between a bump and the piezoelectric vibrating reed, a piezoelectric vibrator having the piezoelectric vibrating reed, a method for manufacturing the piezoelectric vibrator, and an oscillator, an electronic apparatus, and a radio-controlled timepiece each having the piezoelectric vibrator.

In order to solve the problems, the invention provides the following means.

According to an aspect of the invention, there is provided a piezoelectric vibrating reed including: a vibrating portion; a base portion adjacent to the vibrating portion; an excitation electrode formed in the vibrating portion; a mount electrode formed in the base portion; and an extraction electrode for electrically connecting the excitation electrode and the mount electrode to each other, in which a bonding film made of gold is formed on a surface of the mount electrode, and the bonding film is formed to a thickness such that, when the bonding film is ultrasonically bonded to a bump made of gold, mutual diffusion occurs over approximately the entire area in the thickness direction of the bonding film.

According to the piezoelectric vibrating reed of the above aspect of the present invention, when the bump and the mount electrode are ultrasonically bonded to each other, it is possible to cause mutual diffusion over approximately the entire area in the thickness direction of the bonding film which is made of gold and formed on the surface of the mount electrode. Therefore, it is possible to prevent the occurrence of an area of the bonding film where no mutual diffusion occurs at the bonding place between the bump and the mount electrode. Thus, it is possible to secure a stable bonding strength between the bump and the piezoelectric vibrating reed. Moreover, simply by forming such a thin bonding film, it becomes unnecessary to form a plurality of bumps at one bonding place to perform ultrasonic bonding in order to secure a bonding strength. Thus, it is possible to improve production efficiency.

In addition, according to another aspect of the present invention, there is provided a piezoelectric vibrator including: a base substrate; a lid substrate bonded to the base substrate in a state of facing the base substrate; a piezoelectric vibrating reed accommodated in a cavity which is formed between the base substrate and the lid substrate, in which the piezoelectric vibrating reed includes: a vibrating portion; a base portion adjacent to the vibrating portion; an excitation electrode formed in the vibrating portion; a mount electrode formed in the base portion; and an extraction electrode for electrically connecting the excitation electrode and the mount electrode to each other, in which a penetration electrode is provided in a penetration hole which is formed in the base substrate, and a lead-out electrode is formed in the base substrate in order to make the piezoelectric vibrating reed and the penetration electrode electrically connected to each other, in which a bump made of gold is formed at a predetermined position of the lead-out electrode in order to make the lead-out electrode electrically connected to the mount electrode which is formed in the piezoelectric vibrating reed, in which a bonding film made of gold is formed on a surface of the mount electrode of the piezoelectric vibrating reed, and in which the bonding film is formed to a thickness such that, when the bonding film is ultrasonically bonded to the bump, mutual diffusion occurs over approximately the entire area in the thickness direction of the bonding film.

According to the piezoelectric vibrator of the above aspect of the present invention, when the bump and the mount electrode are ultrasonically bonded to each other, it is possible to cause mutual diffusion over approximately the entire area in the thickness direction of the bonding film which is made of gold and formed on the surface of the mount electrode. Therefore, it is possible to prevent the occurrence of an area of the bonding film where no mutual diffusion occurs at the bonding place between the bump and the mount electrode. Thus, it is possible to secure a stable bonding strength between the bump and the piezoelectric vibrating reed. Moreover, simply by forming such a thin bonding film, it becomes unnecessary to form a plurality of bumps at one bonding place to perform ultrasonic bonding in order to secure a bonding strength. Thus, it is possible to improve production efficiency.

In addition, according to still another aspect of the present invention, there is provided a method for manufacturing a piezoelectric vibrator including: a base substrate; a lid substrate bonded to the base substrate in a state of facing the base substrate; a piezoelectric vibrating reed accommodated in a cavity which is formed between the base substrate and the lid substrate, the piezoelectric vibrating reed including: a vibrating portion; a base portion adjacent to the vibrating portion; an excitation electrode formed in the vibrating portion; a mount electrode formed in the base portion; and an extraction electrode for electrically connecting the excitation electrode and the mount electrode to each other, in which a penetration electrode is provided in a penetration hole which is formed in the base substrate, and a lead-out electrode is formed in the base substrate in order to make the piezoelectric vibrating reed and the penetration electrode electrically connected to each other, and a bump made of gold is formed at a predetermined position of the lead-out electrode in order to make the lead-out electrode electrically connected to the mount electrode which is formed in the piezoelectric vibrating reed. The method includes: a step of forming the lead-out electrode in the base substrate; a step of forming the bump at the predetermined position of the lead-out electrode; and a step of ultrasonically bonding the mount electrode of the piezoelectric vibrating reed to the bump, in which a bonding film made of gold is formed on a surface of the mount electrode of the piezoelectric vibrating reed, and the bonding film is formed to a thickness such that, when the bonding film is ultrasonically bonded to the bump, mutual diffusion occurs over approximately the entire area in the thickness direction of the bonding film.

According to the method of forming the piezoelectric vibrator of the above aspect of the present invention, when the bump and the mount electrode are ultrasonically bonded to each other, it is possible to cause mutual diffusion over approximately the entire area in the thickness direction of the bonding film which is made of gold and formed on the surface of the mount electrode. Therefore, it is possible to prevent the occurrence of an area of the bonding film where no mutual diffusion occurs at the bonding place between the bump and the mount electrode. Thus, it is possible to secure a stable bonding strength between the bump and the piezoelectric vibrating reed. Moreover, simply by forming such a thin bonding film, it becomes unnecessary to form a plurality of bumps at one bonding place to perform ultrasonic bonding in order to secure a bonding strength. Thus, it is possible to improve production efficiency.

In addition, according to still another aspect of the invention, there is provided an oscillator in which the above-described piezoelectric vibrator is electrically connected to an integrated circuit as an oscillating piece.

In addition, according to still another aspect of the invention, there is provided an electronic apparatus in which the above-described piezoelectric vibrator is electrically connected to a clock section.

In addition, according to still another aspect of the invention, there is provided a radio-controlled timepiece in which the above-described piezoelectric vibrator is electrically connected to a filter section.

Since each of the oscillator, electronic apparatus, and radio-controlled timepiece according to the above aspects of the present invention includes the piezoelectric vibrator capable of securing a stable bonding strength between the piezoelectric vibrating reed and the bump, it is possible to provide an oscillator, an electronic apparatus, and a radio-controlled timepiece having improved yield and a stable quality.

According to the piezoelectric vibrator of the above aspect of the present invention, when the bump and the mount electrode are ultrasonically bonded to each other, it is possible to cause mutual diffusion over approximately the entire area in the thickness direction of the bonding film which is made of gold and formed on the surface of the mount electrode. Therefore, it is possible to prevent the occurrence of an area of the bonding film where no mutual diffusion occurs at the bonding place between the bump and the mount electrode. Thus, it is possible to secure a stable bonding strength between the bump and the piezoelectric vibrating reed. Moreover, simply by forming such a thin bonding film, it becomes unnecessary to form a plurality of bumps at one bonding place to perform ultrasonic bonding in order to secure a bonding strength. Thus, it is possible to improve production efficiency.

### BRIEF DESCRIPTION OF THE DRAWINGS

FIG. 1 is a perspective view showing an external appearance of a piezoelectric vibrator according to an embodiment of the present invention.

FIG. 2 is a top view showing an inner structure of the piezoelectric vibrator shown in FIG. 1 when a piezoelectric vibrating reed is viewed from above with a lid substrate removed.

FIG. 3 is a sectional view of the piezoelectric vibrator taken along the line A-A in FIG. 2.

FIG. 4 is an exploded perspective view of the piezoelectric vibrator shown in FIG. 1.

FIG. 5 is a top view of the piezoelectric vibrating reed that constitutes the piezoelectric vibrator shown in FIG. 1.

FIG. 6 is a bottom view of the piezoelectric vibrating reed shown in FIG. 5.

FIG. 7 is a sectional view taken along the line B-B in FIG. 5.

FIG. 8 is an enlarged view of the part D in FIG. 3.

FIG. 9 is a flowchart showing the flow of the manufacturing process of the piezoelectric vibrator shown in FIG. 1.

FIG. 10 is a view showing one step of the manufacturing process of the piezoelectric vibrator in accordance with the flowchart shown in FIG. 9, showing a state where a plurality of recess portions is formed on a lid substrate wafer serving as a base material of a lid substrate.

FIG. 11 is a view showing one step of the manufacturing process of the piezoelectric vibrator in accordance with the flowchart shown in FIG. 9, showing a state where a pair of through-holes is formed on a base substrate wafer serving as a base material of a base substrate.

FIG. 12 is a view showing one step of the manufacturing process of the piezoelectric vibrator in accordance with the flowchart shown in FIG. 9, showing a state where the recess portion formed on the base substrate wafer is polished in order to form the through-hole.

FIG. 13 is a view showing the state shown in FIG. 11 when the state is viewed from the section of the base substrate wafer.

FIG. 14 is a perspective view of a rivet member used for manufacturing the piezoelectric vibrator in accordance with the flowchart shown in FIG. 9.

FIG. 15 is a view showing one step of the manufacturing process of the piezoelectric vibrator in accordance with the flowchart shown in FIG. 9, showing a state where the rivet member is disposed in the through-hole, and a glass frit is filled in the through-hole.

FIG. 16 is a view showing one step of the manufacturing process of the piezoelectric vibrator in accordance with the flowchart shown in FIG. 9, showing a state where a redundant glass frit is being removed.

FIG. 17 is a view showing one step of the manufacturing process of the piezoelectric vibrator in accordance with the flowchart shown in FIG. 9, showing a state where the redundant glass frit was removed.

FIG. 18 is a view showing one step of the manufacturing process of the piezoelectric vibrator in accordance with the flowchart shown in FIG. 9, showing a state where the glass frit was baked, subsequent to the state shown in FIG. 17.

FIG. 19 is a view showing one step of the manufacturing process of the piezoelectric vibrator in accordance with the flowchart shown in FIG. 9, showing a state where a base portion of the rivet member and the base substrate wafer were polished, subsequent to the state shown in FIG. 18.

FIG. 20 is a view showing one step of the manufacturing process of the piezoelectric vibrator in accordance with the flowchart shown in FIG. 9, showing a state where a bonding film and a lead-out electrode are patterned on the upper surface of the base substrate wafer, subsequent to the state shown in FIG. 19.

FIG. 21 is an overall view of the base substrate wafer in the state shown in FIG. 20.

FIG. 22 is an exploded perspective view showing one step of the manufacturing process of the piezoelectric vibrator in accordance with the flowchart shown in FIG. 9, showing a wafer assembly in which the base substrate wafer and the lid substrate wafer are anodically bonded with the piezoelectric vibrating reed accommodated in the cavity.

FIG. 23 is a view showing the configuration of an oscillator according to an embodiment of the present invention.

FIG. 24 is a view showing the configuration of an electronic apparatus according to an embodiment of the present invention.

FIG. 25 is a view showing the configuration of a radio-controlled timepiece according to an embodiment of the present invention.

### DETAILED DESCRIPTION OF THE PREFERRED EMBODIMENTS

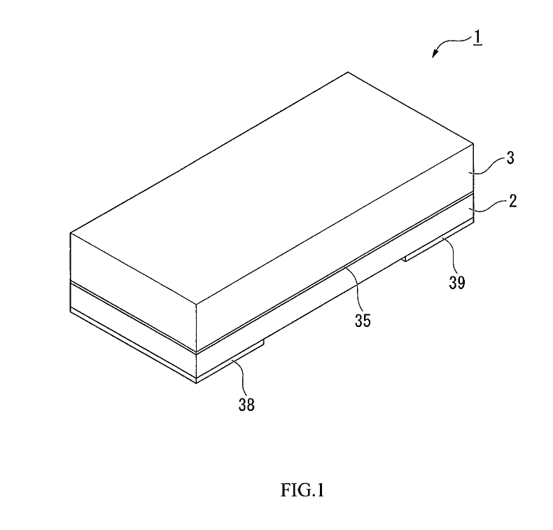

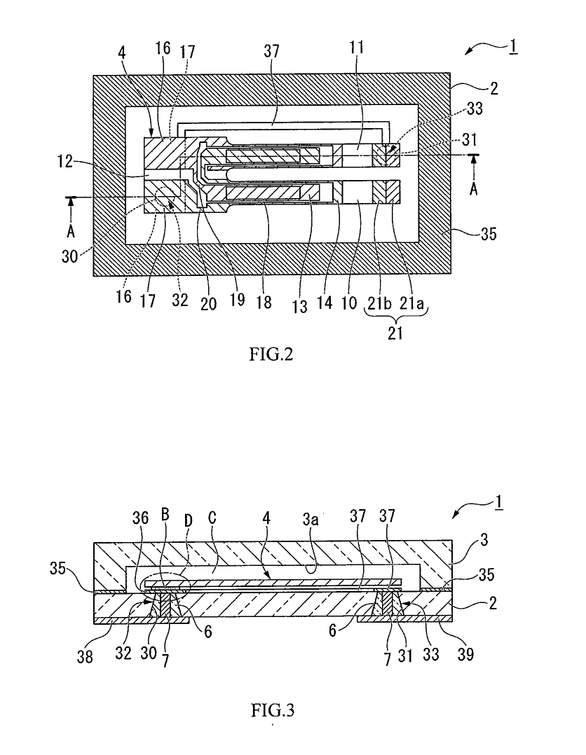

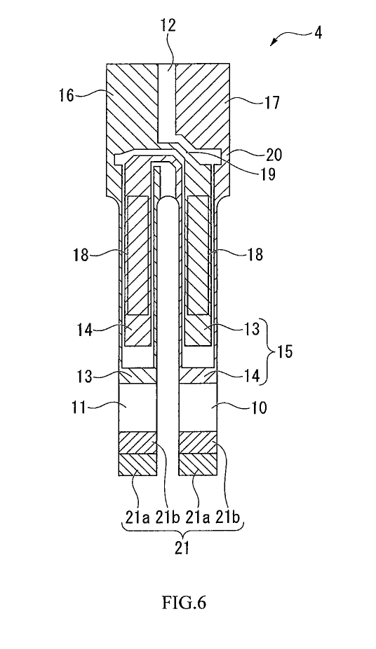

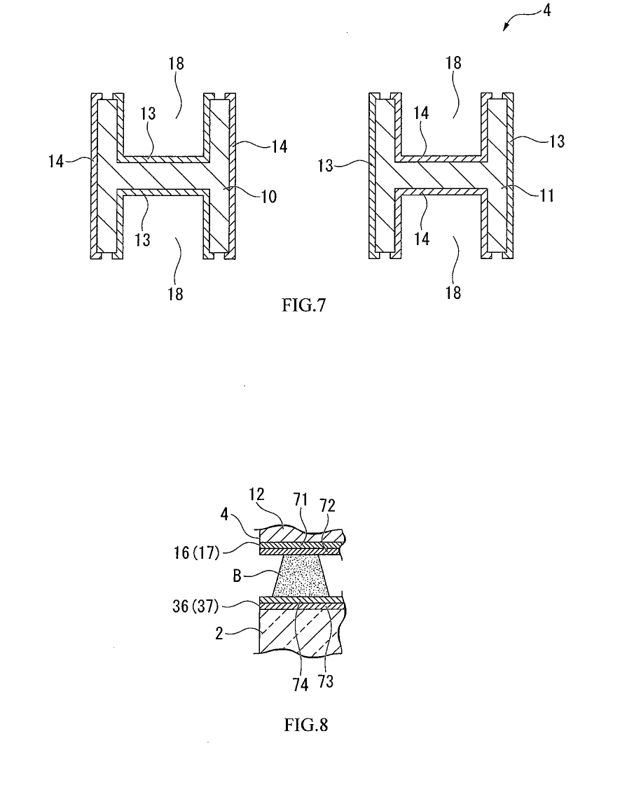

Hereinafter, an embodiment of the present invention will be described with reference to FIGS. 1 to 25. In the present embodiment, a piezoelectric vibrator using a tuning-fork type piezoelectric vibrating reed will be described.

As shown in FIGS. 1 to 4, a piezoelectric vibrator 1 according to the present embodiment is a surface mounted device-type piezoelectric vibrator which is formed in the form of a box laminated in two layers of a base substrate 2 and a lid substrate 3 and in which a tuning-fork type piezoelectric vibrating reed 4 is accommodated in a cavity C at an inner portion thereof. In FIG. 4, for better understanding of the drawings, illustrations of the excitation electrode 15, extraction electrodes 19 and 20, mount electrodes 16 and 17, and weight metal film 21 are omitted.

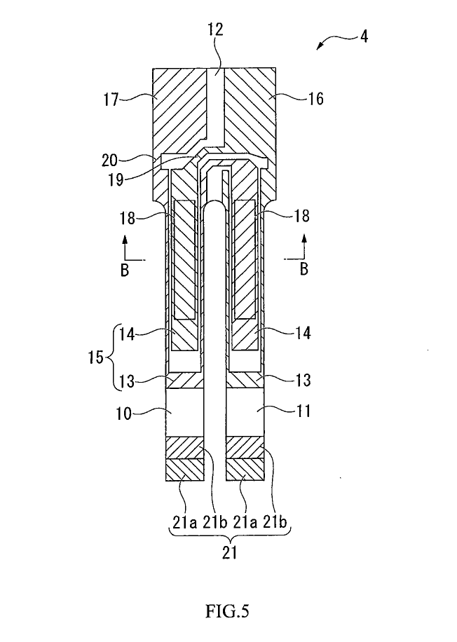

As shown in FIGS. 5 to 7, the piezoelectric vibrating reed 4 is a tuning-fork type vibrating reed which is made of a piezoelectric material such as crystal, lithium tantalate, or lithium niobate and is configured to vibrate when a predetermined voltage is applied thereto.

The piezoelectric vibrating reed 4 includes: a pair of vibrating arms 10 and 11 disposed in parallel to each other; a base portion 12 to which the base end sides of the pair of vibrating arms 10 and 11 are integrally fixed; an excitation electrode 15 which is made up of a first excitation electrode 13 and a second excitation electrode 14 which are formed on the outer surfaces of the pair of vibrating arms 10 and 11 so as to allow the pair of vibrating arms 10 and 11 to vibrate; and mount electrodes 16 and 17 which are electrically connected to the first excitation electrode 13 and the second excitation electrode 14, respectively.

In addition, the piezoelectric vibrating reed 4 according to the present embodiment is provided with groove portions 18 which are formed on both principal surfaces of the pair of vibrating arms 10 and 11 along the longitudinal direction of the vibrating arms 10 and 11. The groove portions 18 are formed so as to extend from the base end sides of the vibrating arms 10 and 11 up to approximately the middle portions thereof.

The excitation electrode 15 including the first excitation electrode 13 and the second excitation electrode 14 is an electrode that allows the pair of vibrating arms 10 and 11 to vibrate at a predetermined resonance frequency in a direction moving closer to or away from each other and is patterned on the outer surfaces of the pair of vibrating arms 10 and 11 in an electrically isolated state. Specifically, the first excitation electrode 13 is mainly formed on the groove portion 18 of one vibrating arm 10 and both side surfaces of the other vibrating arm 11. On the other hand, the second excitation electrode 14 is mainly formed on both side surfaces of one vibrating arm 10 and the groove portion 18 of the other vibrating arm 11.

Moreover, the first excitation electrode 13 and the second excitation electrode 14 are electrically connected to the mount electrodes 16 and 17 via the extraction electrodes 19 and 20, respectively, on both principal surfaces of the base portion 12. A voltage is applied to the piezoelectric vibrating reed 4 via the mount electrodes 16 and 17.

The above-mentioned excitation electrode 15, mount electrodes 16 and 17, and extraction electrodes 19 and 20 are formed, for example, by a coating of chromium (Cr) which is a conductive material. Moreover, as shown in FIG. 8, on the bonding surfaces of the mount electrodes 16 and 17 bonded to the bumps B, a bonding film 72 made of gold (Au) is further formed on a coating (a base film 71) which is made of chromium. For example, the base film 71 is formed to a thickness of about 500 to 600 Å, and the bonding film 72 is formed to a thickness of about 500 to 600 Å. That is, the bonding film 72 is formed as a thin film. As the coating of the respective electrodes, in addition to the above-mentioned material, nickel (Ni), aluminum (Al), titanium (Ti), or the like may be used.

Furthermore, the tip ends of the pair of the vibrating arms 10 and 11 are coated with a weight metal film 21 for mass adjustment of the vibration states (tuning the frequency) of the vibrating arms 10 and 11 in a manner such as to vibrate within a predetermined frequency range. The weight metal film 21 is divided into a rough tuning film 21 a used for tuning the frequency roughly and a fine tuning film 21b used for tuning the frequency finely. By tuning the frequency with the use of the rough tuning film 21a and the fine tuning film 21b, the frequency of the pair of the vibrating arms 10 and 11 can be set to fall within the range of the nominal (target) frequency of the device.

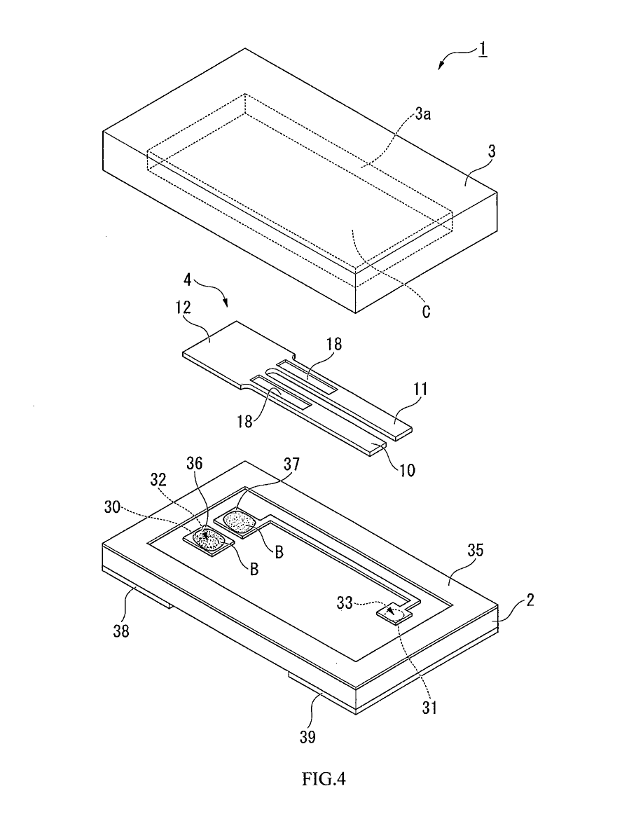

The piezoelectric vibrating reed 4 configured in this way is bump-bonded to the upper surface of the base substrate 2 by a bump B made of gold or the like as shown in FIGS. 3 and 4. More specifically, bump-bonding is achieved by ultrasonic bonding on the like in a state where the pair of mount electrodes 16 and 17 come into contact with two bumps B formed on the lead-out electrodes 36 and 37, respectively, which are patterned on the upper surface of the base substrate 2. In this way, the piezoelectric vibrating reed 4 is supported in a state of being floated from the upper surface of the base substrate 2, and the mount electrodes 16 and 17 and the lead-out electrodes 36 and 37 are electrically connected to each other.

The lid substrate 3 is a transparent insulating substrate made of a glass material, for example, soda-lime glass, and is formed in a substrate-like form as shown in FIGS. 1, 3, and 4. A bonding surface side thereof to be bonded to the base substrate 2 is formed with a rectangular recess portion 3a in which the piezoelectric vibrating reed 4 is accommodated. The recess portion 3a is a recess portion for a cavity serving as the cavity C that accommodates the piezoelectric vibrating reed 4 when the two substrates 2 and 3 are superimposed onto each other. The lid substrate 3 is anodically bonded to the base substrate 2 in a state where the recess portion 3a faces the base substrate 2.

The base substrate 2 is a transparent insulating substrate made of glass material, for example, soda-lime glass, similarly to the lid substrate 3, and is formed in a substrate-like form having a size capable of being overlapped with the lid substrate 3, as shown in FIGS. 1 to 4.

The base substrate 2 is formed with a pair of through-holes (penetration holes) 30 and 31 penetrating through the base substrate 2. At this time, the pair of through-holes 30 and 31 is formed so as to be received in the cavity C. More specifically, the through-holes 30 and 31 of the present embodiment are formed such that one through-hole 30 is positioned at a corresponding position close to the base portion 12 of the mounted piezoelectric vibrating reed 4, and the other through-hole 31 is positioned at a corresponding position close to the tip ends of the vibrating arms 10 and 11. In addition, the through-holes 30 and 31 of the present embodiment are formed in a tapered form whose diameter gradually increases from the upper surface of the base substrate 2 towards the lower surface.

The pair of through-holes 30 and 31 is formed with a pair of penetration electrodes 32 and 33 which are formed so as to bury the through-holes 30 and 31. As shown in FIG. 3, the penetration electrodes 32 and 33 are formed by a cylindrical member 6 and a core portion 7 which are integrally fixed to the through-holes 30 and 31 by baking. The penetration electrodes 32 and 33 serve to maintain air-tightness of the inside of the cavity C by completely closing the through-holes 30 and 31 and achieving electrical connection between the outer electrodes 38 and 39 described later and the lead-out electrodes 36 and 37.

The cylindrical member 6 is obtained by baking a paste-like glass frit. The cylindrical member 6 has a cylindrical shape of which both ends are flat and which has approximately the same thickness as the base substrate 2. A core portion 7 is disposed at the center of the cylindrical member 6 so as to penetrate through the cylindrical member 6. As shown in FIG. 3, the cylindrical member 6 is baked in a state of being buried in the through-holes 30 and 31 and is tightly attached to the through-holes 30 and 31.

The core portion 7 is a conductive cylindrical core material made of metallic material, and similarly to the cylindrical member 6, has a shape which has flat ends and approximately the same thickness as the base substrate 2. As shown in FIG. 3, when the penetration electrodes 32 and 33 are formed as a finished product, the core portion 7 has approximately the same thickness as the base substrate 2 as described above. However, in the course of the manufacturing process, the length of the core portion 7 is smaller than the thickness of the base substrate 2 in the initial state of the manufacturing process. The core portion 7 is tightly attached to the cylindrical member 6 by the baking of the cylindrical member 6. The electrical connection of the penetration electrodes 32 and 33 is secured via the conductive core portion 7.

As shown in FIGS. 1 to 4, on the upper surface side of the base substrate 2 (the bonding surface side to be bonded to the lid substrate 3), a bonding film 35 for anodic bonding and the pair of lead-out electrodes 36 and 37 are patterned by a conductive material. Among them, the bonding film 35 is formed along the peripheral edge of the base substrate 2 so as to surround the periphery of the recess portion 3a formed on the lid substrate 3. Moreover, as shown in FIG. 8, in the present embodiment, on the lead-out electrodes 36 and 37, a bonding film 74 made of gold (Au) is further formed on a coating (a base film 73), for example, of chromium (Cr) which is a conductive material. For example, the base film 73 is formed to a thickness of about 500 to 600 Å, and the bonding film 74 is formed to a thickness of about 1000 to 1500 Å.

Moreover, the pair of lead-out electrodes 36 and 37 is patterned so that one penetration electrode 32 of the pair of penetration electrodes 32 and 33 is electrically connected to one mount electrode 16 of the piezoelectric vibrating reed 4, and the other penetration electrode 33 is electrically connected to the other mount electrode 17 of the piezoelectric vibrating reed 4.

More specifically, one lead-out electrode 36 is formed right above the one penetration electrode 32 to be disposed right below the base portion 12 of the piezoelectric vibrating reed 4. Moreover, the other lead-out electrode 37 is formed to be disposed right above the other penetration electrode 33 after being led out from a position near the one lead-out electrode 36 towards the tip ends of the vibrating arms 10 and 11 along the vibrating arms 10 and 11.

The bumps B are formed on the pair of lead-out electrodes 36 and 37, and the piezoelectric vibrating reed 4 is mounted using the bumps B. In this way, the one mount electrode 16 of the piezoelectric vibrating reed 4 is electrically connected to the one penetration electrode 32 via the one lead-out electrode 36, and the other mount electrode 17 is electrically connected to the other penetration electrode 33 via the other lead-out electrode 37.

Moreover, the lower surface of the base substrate 2 is formed with the outer electrodes 38 and 39 which are electrically connected to the pair of penetration electrodes 32 and 33, respectively, as shown in FIGS. 1, 3, and 4. That is, one outer electrode 38 is electrically connected to the first excitation electrode 13 of the piezoelectric vibrating reed 4 via the one penetration electrode 32 and the one lead-out electrode 36. In addition, the other outer electrode 39 is electrically connected to the second excitation electrode 14 of the piezoelectric vibrating reed 4 via the other penetration electrode 33 and the other lead-out electrode 37.

When the piezoelectric vibrator 1 configured in this manner is operated, a predetermined drive voltage is applied between the pair of outer electrodes 38 and 39 formed on the base substrate 2. In this way, a current can be made to flow to the excitation electrode 15 including the first and second excitation electrodes 13 and 14, of the piezoelectric vibrating reed 4, and the pair of vibrating arms 10 and 11 is allowed to vibrate at a predetermined frequency in a direction moving closer to or away from each other. This vibration of the pair of vibrating arms 10 and 11 can be used as the time source, the timing source of a control signal, the reference signal source, and the like.

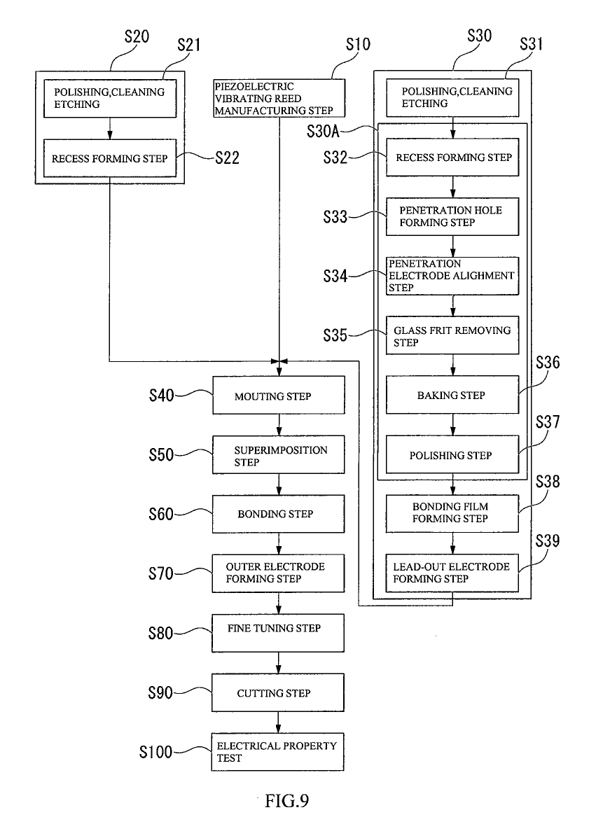

Next, a method for manufacturing a plurality of the above-described piezoelectric vibrators 1 at one time using a base substrate wafer 40 and a lid substrate wafer 50 will be described with reference to the flowchart shown in FIG. 9.

First, a piezoelectric vibrating reed manufacturing step is performed to manufacture the piezoelectric vibrating reed 4 shown in FIGS. 5 to 7 (S10). Specifically, first, a rough crystal Lambert is sliced at a predetermined angle to obtain a wafer having a constant thickness. Subsequently, the wafer is subjected to crude processing by lapping, and an affected layer is removed by etching. Then, the wafer is subjected to mirror processing such as polishing to obtain a wafer having a predetermined thickness. Subsequently, the wafer is subjected to appropriate processing such as washing, and the wafer is patterned so as to have the outer shape of the piezoelectric vibrating reed 4 by a photolithography technique. Moreover, a metal film is formed and patterned on the wafer, thus forming the excitation electrode 15, the extraction electrodes 19 and 20, the mount electrodes 16 and 17, and the weight metal film 21. In this way, a plurality of piezoelectric vibrating reeds 4 can be manufactured. In the present embodiment, on at least the mount electrodes 16 and 17, a chromium film is formed to a thickness of about 500 to 600 Å as the base film 71, and a gold film is formed to a thickness of about 500 to 600 Å as the bonding film 72.

Moreover, after the piezoelectric vibrating reed 4 is manufactured, rough tuning of a resonance frequency is performed. This rough tuning is achieved by irradiating the rough tuning film 21a of the weight metal film 21 with a laser beam to evaporate in part the rough tuning film 21a, thus changing the weight thereof. Fine tuning of adjusting the resonance frequency more accurately is performed after a mounting step is performed. This fine tuning will be described later.

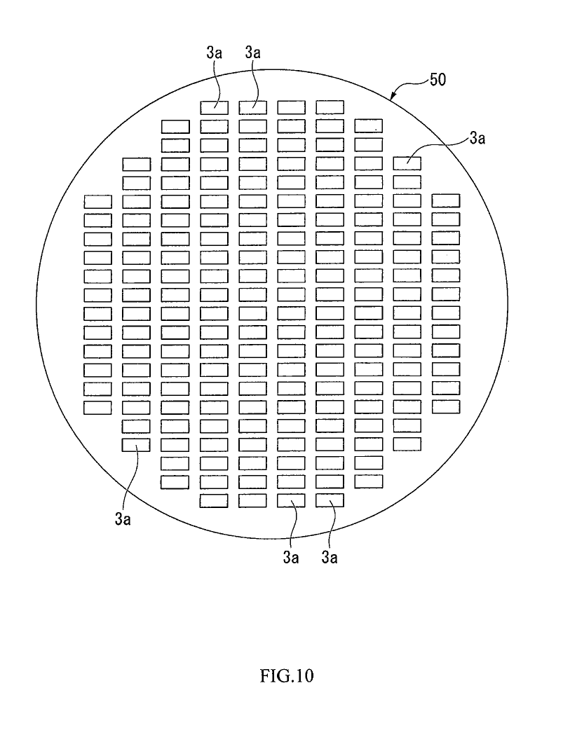

Subsequently, a first wafer manufacturing step is performed where the lid substrate wafer 50 later serving as the lid substrate 3 is manufactured up to a stage immediately before anodic bonding is achieved (S20). In this step, first, a disk-shaped lid substrate wafer 50 is formed by polishing a soda-lime glass to a predetermined thickness, cleaning the polished glass, and removing the affected uppermost layer by etching or the like (S21). Subsequently, as shown in FIG. 10, a recess forming step is performed where a plurality of recess portions 3a to be used as a cavity C is formed in a matrix form on the bonding surface of the lid substrate wafer 50 by etching or the like (S22). The first wafer manufacturing step ends at this point in time.

Subsequently, at the same or a different time as the first wafer manufacturing step, a second wafer manufacturing step is performed where a base substrate wafer 40 later serving as the base substrate 2 is manufactured up to a stage immediately before anodic bonding is achieved (S30). In this step, first, a disk-shaped base substrate wafer 40 is formed by polishing a soda-lime glass to a predetermined thickness, cleaning the polished glass, and removing the affected uppermost layer by etching or the like (S31). Subsequently, a penetration electrode forming step is performed where a plurality of pairs of penetration electrodes 32 and 33 is formed on the base substrate wafer 40 (S30A). The penetration electrode forming step will be described in detail below.

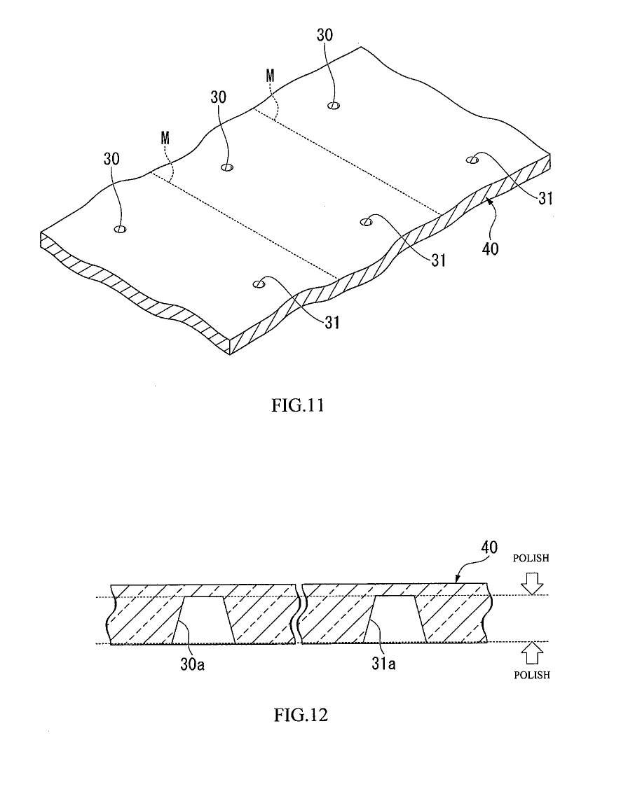

First, as shown in FIG. 11, a recess forming step is performed where recess portions 30a and 31a are formed on the base substrate wafer 40 so as to correspond to the pair of through-holes 30 and 31 (S32). The dotted line M shown in FIG. 11 is a cutting line along which a cutting step performed later is achieved.

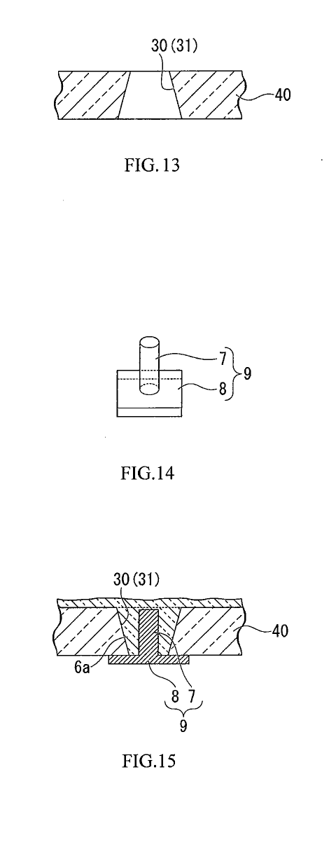

Subsequently, a penetration hole forming step is performed where a plurality of pairs of through-holes 30 and 31 is formed so as to penetrate through the base substrate wafer 40 (S33). When the through-holes 30 and 31 are formed on the base substrate wafer 40, as shown in FIG. 12, both surfaces of the base substrate wafer 40 are polished. Moreover, as shown in FIG. 13, a plurality of through-holes 30 and 31 is formed in a tapered form whose diameter gradually increases from the upper surface of the base substrate wafer 40 towards the lower surface thereof. One through-hole 30 is formed to be positioned close to the base portion 12 of the piezoelectric vibrating reed 4, and the other through-hole 31 is formed to be positioned close to the tip ends of the vibrating arms 10 and 11.

Subsequently, a penetration electrode alignment step is performed where the core portions 7 of the rivet members 9 are disposed in the plurality of through-holes 30 and 31, and a paste-like glass frit 6a made of a glass material is filled into the through-holes 30 and 31 (S34). At that time, as shown in FIG. 14, as the rivet member 9, a conductive rivet member 9 which has a planar base portion 8 and a core portion 7 which extends upwardly from the base portion 8 in a direction approximately perpendicular to the surface of the base portion 8 and has a length slightly shorter (for example, by about 0.02 mm) than the thickness of the base substrate wafer 40 and a flat tip end is used. As shown in FIG. 15, the core portion 7 is inserted until the base portion 8 of the rivet member 9 comes into contact with the base substrate wafer 40. Here, it is necessary to dispose the rivet member 9 so that the axial direction of the core portion 7 is approximately identical to the axial direction of the through-holes 30 and 31. In the present embodiment, since the rivet member 9 having the core portion 7 formed on the base portion 8 is used, it is possible to make the axial direction of the core portion 7 approximately identical to the axial direction of the through-holes 30 and 31 by a simple operation of pushing the base portion 8 until the base portion 8 comes into contact with the base substrate wafer 40. Therefore, it is possible to improve workability during the penetration electrode alignment step.

In addition, by bringing the base portion 8 into contact with the surface of the base substrate wafer 40, it is possible to securely fill the paste-like glass frit 6a into the through-holes 30 and 31.

Since the base portion 8 has a planar shape, the base substrate wafer 40 can be placed stably on a flat surface of a desk or the like without any rattling during periods between the penetration electrode alignment step and a baking step performed later. In this respect, it is possible to achieve an improvement in the workability.

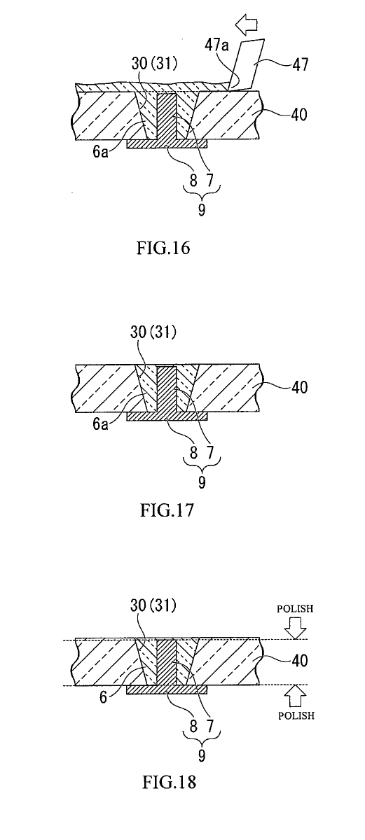

When the glass frit 6a is filled into the through-holes 30 and 31, a sufficient amount of the glass frit 6a is applied so that the glass frit 6a is securely filled into the through-holes 30 and 31. Therefore, the glass frit 6a is also applied onto the surface of the base substrate wafer 40. When the glass frit 6a is baked in this state, since a subsequent polishing step may take a lot of time, a glass frit removal step is performed to remove the redundant glass frit 6a before the baking (S35). As shown in FIG. 16, in the glass frit removal step, the glass frit 6a is removed by moving a squeegee 47 made of resin, for example, along the surface of the base substrate wafer 40 with a tip end 47a of the squeegee 47 coming into contact with the surface of the base substrate wafer 40. By doing so, as shown in FIG. 17, the redundant glass frit 6a can be removed securely by a simple operation. In the present embodiment, the length of the core portion 7 of the rivet member 9 is made slightly shorter than the thickness of the base substrate wafer 40. Therefore, when the squeegee 47 passes over the through-holes 30 and 31, the tip end 47a of the squeegee 47 will not make contact with the tip end of the core portion 7. Thus, it is possible to prevent the core portion 7 from being tilted.

Subsequently, a baking step is performed where the buried filling material is baked at a predetermined temperature (S36). Through the baking step, the through-holes 30 and 31, the glass frit 6a buried in the through-holes 30 and 31, and the core portions 7 disposed in the glass frit 6a are attached to each other. Since the baking is performed for each base portion 8, the through-holes 30 and 31 and the core portions 7 can be integrally fixed to each other in a state where the axial direction of the core portion 7 is approximately identical to the axial direction of the through-holes 30 and 31. The baked glass frit 6a is solidified as the cylindrical member 6.

Subsequently, as shown in FIG. 18, after the baking step, a polishing step is performed where the base portions 8 of the rivet members 9 are polished and removed (S37). In this way, it is possible to remove the base portions 8 that achieved positioning of the cylindrical member 6 and the core portions 7, allowing only the core portions 7 to remain inside the cylindrical member 6.

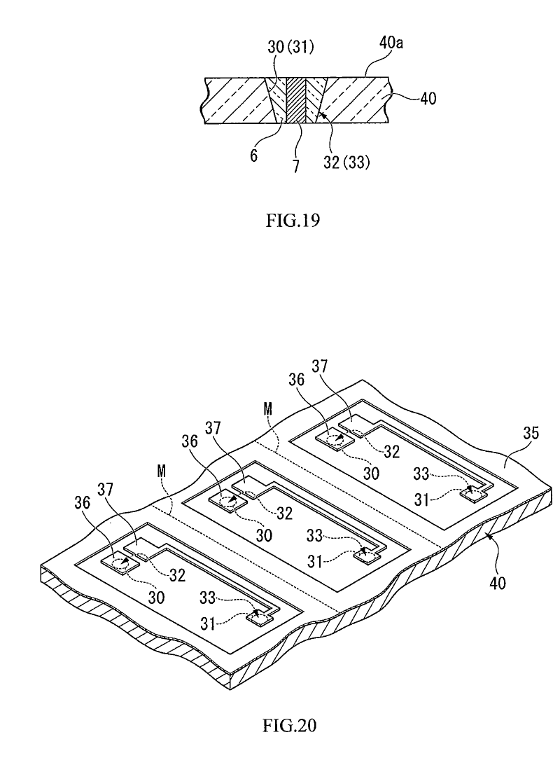

At the same time, the rear surface (the surface where the base portion 8 of the rivet member 9 is not disposed) of the base substrate wafer 40 is polished to obtain a flat surface. The polishing is continued until the tip end of the core portion 7 is exposed. As a result, as shown in FIG. 19, it is possible to obtain a plurality of pairs of penetration electrodes 32 and 33 in which the cylindrical member 6 and the core portion 7 are integrally fixed.

As described above, the surfaces of the base substrate wafer 40 are approximately flush with both ends of the cylindrical member 6 and the core portion 7. That is to say, it is possible to make the surfaces of the base substrate wafer 40 approximately flush with the surfaces of the penetration electrodes 32 and 33. The penetration electrode forming step (S30A) ends at the point of time when the polishing step is performed.

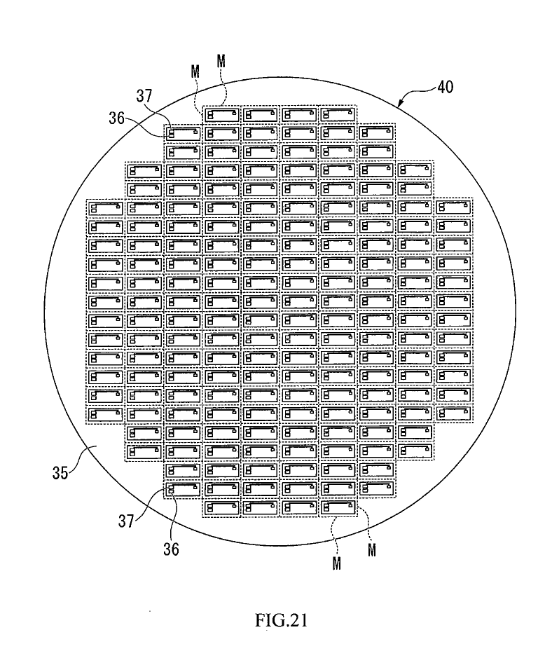

Subsequently, a bonding film forming step is performed where a conductive material is patterned on the upper surface of the base substrate wafer 40 so as to form a bonding film 35 as shown in FIGS. 20 and 21 (S38). Moreover, a lead-out electrode forming step is performed where a plurality of lead-out electrodes 36 and 37 is formed so as to be electrically connected to each pair of penetration electrodes 32 and 33, respectively (S39). In the present embodiment, on at least the lead-out electrodes 36 and 37, a chromium film is formed to a thickness of about 500 to 600 Å as the base film 73, and a gold film is formed to a thickness of about 1000 to 1500 Å as the bonding film 74. The dotted line M shown in FIGS. 20 and 21 is a cutting line along which a cutting step performed later is achieved.

Particularly, as described above, the penetration electrodes 32 and 33 are approximately flush with the upper surface of the base substrate wafer 40. Therefore, the lead-out electrodes 36 and 37 which are patterned on the upper surface of the base substrate wafer 40 are closely adhered onto the penetration electrodes 32 and 33 without forming any gap or the like therebetween. In this way, it is possible to achieve reliable electrical connection between the one lead-out electrode 36 and the one penetration electrode 32 and reliable electrical connection between the other lead-out electrode 37 and the other penetration electrode 33. The second wafer manufacturing step ends at this point in time.

In FIG. 9, although the lead-out electrode forming step (S39) is performed after the bonding film forming step (S38), conversely, the bonding film forming step (S38) may be performed after the lead-out electrode forming step (S39), and the two steps may be performed at the same time. The same operational effect can be obtained with any order of the steps. Therefore, the order of the steps may be appropriately changed as necessary.

Subsequently, a mounting step is performed where a plurality of manufactured piezoelectric vibrating reeds 4 is bonded to the upper surface of the base substrate wafer 40 via the lead-out electrodes 36 and 37 (S40). First, bumps B made of gold are formed on the pair of lead-out electrodes 36 and 37 by means of wire bonding or the like. Thereafter, the lead-out electrodes 36 and 37 and the bumps B are bonded to each other by ultrasonic bonding. At that time, the gold of the lead-out electrodes 36 and 37 and the gold of the bumps B are mutually diffused, whereby a bonding strength is secured.

The base portion 12 (the mount electrodes 16 and 17) of the piezoelectric vibrating reed 4 is placed on the bumps B. Thereafter, the piezoelectric vibrating reed 4 is pressed against the bumps B while heating the bumps B to a predetermined temperature, and ultrasonic waves are applied so as to achieve bonding. In this way, the piezoelectric vibrating reed 4 is mechanically supported by the bumps B, and the mount electrodes 16 and 17 are electrically connected to the lead-out electrodes 36 and 37. Therefore, at this point in time, the pair of excitation electrodes 15 of the piezoelectric vibrating reed 4 is electrically connected to the pair of penetration electrodes 32 and 33, respectively. Particularly, since the piezoelectric vibrating reed 4 is bump-bonded, the piezoelectric vibrating reed 4 is supported in a state of being floated from the upper surface of the base substrate wafer 40.

In the present embodiment, the bonding film 72 which is made of gold and formed on the mount electrodes 16 and 17 has a small thickness. Thus, when the bonding film 72 is ultrasonically bonded to the bumps B, the gold of the mount electrodes 16 and 17 and the gold of the bumps B are mutually diffused over approximately the entire area in the thickness direction of the bonding film 72. Thus, The mount electrodes 16 and 17 and the bumps B are bonded by a stable bonding strength. Moreover, the gold of the lead-out electrodes 36 and 37 and the gold of the bumps B are mutually diffused again, whereby a bonding strength can be further increased.

After the piezoelectric vibrating reed 4 is mounted, a superimposition step is performed where the lid substrate wafer 50 is superimposed onto the base substrate wafer 40 (S50). Specifically, both wafers 40 and 50 are aligned at a correct position using reference marks or the like not shown in the figure as indices. In this way, the mounted piezoelectric vibrating reed 4 is accommodated in the recess portion 3a formed on the lid substrate wafer 50, namely in the cavity C which is surrounded by both wafers 40 and 50.

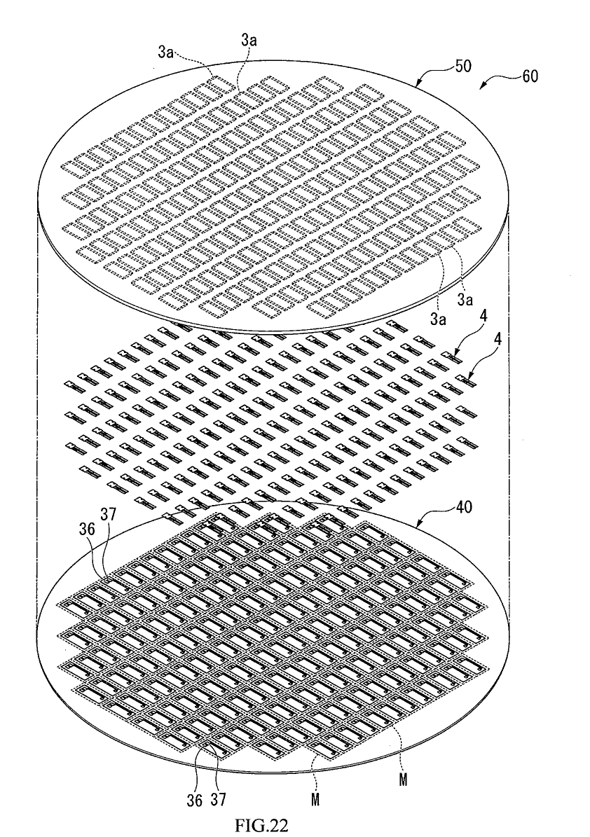

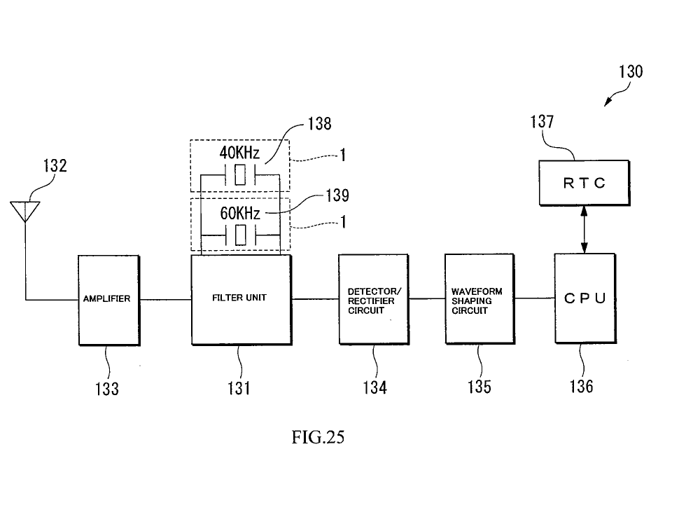

After the superimposition step is performed, a bonding step is performed where the two superimposed wafers 40 and 50 are inserted into an anodic bonding machine not diagrammatically included to achieve anodic bonding under a predetermined temperature and atmosphere with application of a predetermined voltage (S60). Specifically, a predetermined voltage is applied between the bonding film 35 and the lid substrate wafer 50. Then, an electrochemical reaction occurs at an interface between the bonding film 35 and the lid substrate wafer 50, whereby they are closely and tightly adhered and anodically bonded. In this way, the piezoelectric vibrating reed 4 can be sealed in the cavity C, and a wafer assembly 60 shown in FIG. 25 can be obtained in which the base substrate wafer 40 and the lid substrate wafer 50 are bonded to each other. In FIG. 22, for better understanding of the figure, the wafer assembly 60 is illustrated in an exploded state. The dotted line M shown in FIG. 22 is a cutting line along which a cutting step performed later is achieved.

When the anodic bonding is performed, since the through-holes 30 and 31 formed on the base substrate wafer 40 are completely closed by the penetration electrodes 32 and 33, the airtightness in the cavity C will not be impaired by the through-holes 30 and 31. Particularly, since the cylindrical member 6 and the core portion 7 are integrally fixed by the baking, and they are tightly attached to the through-holes 30 and 31, it is possible to reliably maintain airtightness in the cavity C.

After the above-described anodic bonding is completed, an outer electrode forming step is performed where a conductive material is patterned onto the lower surface of the base substrate wafer 40 so as to form a plurality of pairs of outer electrodes 38 and 39 which is electrically connected to the pair of penetration electrodes 32 and 33 (S70). By this step, the piezoelectric vibrating reed 4 which is sealed in the cavity C can be operated using the outer electrodes 38 and 39.

Particularly, when this step is performed, similarly to the step of forming the lead-out electrodes 36 and 37, since the penetration electrodes 32 and 33 are approximately flush with the lower surface of the base substrate wafer 40, the patterned outer electrodes 38 and 39 are closely adhered onto the penetration electrodes 32 and 33 without forming any gap or the like therebetween. In this way, it is possible to achieve reliable electrical connection between the outer electrodes 38 and 39 and the penetration electrodes 32 and 33.

Subsequently, a fine tuning step is performed on the wafer assembly 60 where the frequencies of the individual piezoelectric vibrators 1 sealed in the cavities C are tuned finely to fall within a predetermined range (S80). Specifically, a voltage is applied to the pair of outer electrodes 38 and 39 which is formed on the lower surface of the base substrate wafer 40, thus allowing the piezoelectric vibrating reeds 4 to vibrate. A laser beam is irradiated onto the lid substrate wafer 50 from the outer side while measuring the vibration frequencies to evaporate the fine tuning film 21b of the weight metal film 21. In this way, since the weight on the tip end sides of the pair of vibrating arms 10 and 11 is changed, the fine tuning can be performed in such a way that the frequency of the piezoelectric vibrating reed 4 falls within the predetermined range of the nominal frequency.

After the fine tuning of the frequency is completed, a cutting step is performed where the bonded wafer assembly 60 is cut along the cutting line M shown in FIG. 22 to obtain small fragments (S90). As a result, a plurality of two-layered surface mounted device-type piezoelectric vibrators 1 shown in FIG. 1, in which the piezoelectric vibrating reed 4 is sealed in the cavity C formed between the base substrate 2 and the lid substrate 3 being anodically bonded together, can be manufactured at one time.

The fine tuning step (S80) may be performed after performing the cutting step (S90) to obtain the individual fragmented piezoelectric vibrators 1. However, as described above, by performing the fine tuning step (S80) earlier, since the fine tuning step can be performed on the wafer assembly 60, it is possible to perform the fine tuning on the plurality of piezoelectric vibrators 1 more efficiently. Therefore, it is desirable because throughput can be increased.

Subsequently, an inner electrical property test is conducted (S100). That is, the resonance frequency, resonance resistance value, drive level properties (the excitation power dependence of the resonance frequency and the resonance resistance value), and the like of the piezoelectric vibrating reed 4 are measured and checked. Moreover, the insulation resistance properties and the like are compared and checked as well. Finally, an external appearance test of the piezoelectric vibrator 1 is conducted to check the dimensions, the quality, and the like. In this way, the manufacturing of the piezoelectric vibrator 1 ends.

According to the present embodiment, when the bumps B and the mount electrodes 16 and 17 are ultrasonically bonded to each other, it is possible to cause mutual diffusion over approximately the entire area in the thickness direction of the bonding film 72 which is made of gold and formed on the surfaces of the mount electrodes 16 and 17. That is, it is possible to prevent the occurrence of an area of the bonding film 72 where no mutual diffusion occurs at the bonding place between the bumps B and the mount electrodes 16 and 17. Thus, it is possible to secure a stable bonding strength between the bumps B and the piezoelectric vibrating reed 4. Moreover, simply by forming the bonding film 72 as a thin film, it becomes unnecessary to form a plurality of bumps at one bonding place to perform ultrasonic bonding in order to secure a bonding strength. Thus, it is possible to improve production efficiency.

Moreover, by forming the bonding film 72 of the piezoelectric vibrating reed 4 as a thin film, it is possible to improve the drive level properties of the piezoelectric vibrating reed 4 and improve the performance of the piezoelectric vibrator 1.

Furthermore, since mutual diffusion occurs over approximately the entire area in the thickness direction of the bonding film 72, it is possible to prevent the occurrence of variations in the bonding strength of each product. Therefore, it is possible to obtain the piezoelectric vibrator 1 having improved yield and stable quality.

### Oscillator

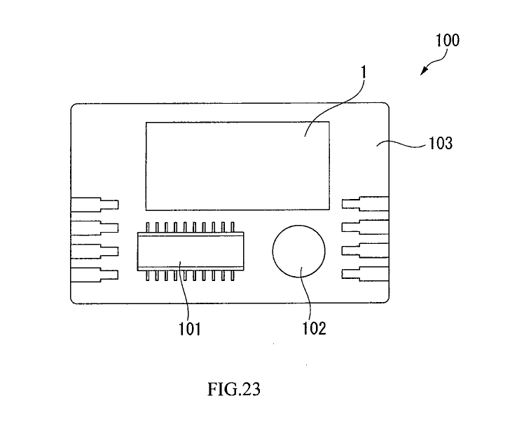

Next, an oscillator according to another embodiment of the invention will be described with reference to FIG. 23.

In an oscillator 100 according to the present embodiment, the piezoelectric vibrator 1 is used as an oscillating piece electrically connected to an integrated circuit 101, as shown in FIG. 23. The oscillator 100 includes a substrate 103 on which an electronic component 102, such as a capacitor, is mounted. The integrated circuit 101 for an oscillator is mounted on the substrate 103, and the piezoelectric vibrator 1 is mounted near the integrated circuit 101. The electronic component 102, the integrated circuit 101, and the piezoelectric vibrator 1 are electrically connected to each other by a wiring pattern (not shown). In addition, each of the constituent components is molded with a resin (not shown).

In the oscillator 100 configured as described above, when a voltage is applied to the piezoelectric vibrator 1, the piezoelectric vibrating reed 4 in the piezoelectric vibrator 1 vibrates. This vibration is converted into an electrical signal due to the piezoelectric property of the piezoelectric vibrating reed 4 and is then input to the integrated circuit 101 as the electrical signal. The input electrical signal is subjected to various kinds of processing by the integrated circuit 101 and is then output as a frequency signal. In this way, the piezoelectric vibrator 1 functions as an oscillator.

Moreover, by selectively setting the configuration of the integrated circuit 101, for example, an RTC (real time clock) module, according to the demands, it is possible to add a function of controlling the operation date or time of the corresponding device or an external device or of providing the time or calendar in addition to a single functional oscillator for a clock.

As described above, since the oscillator 100 according to the present embodiment includes the piezoelectric vibrator 1 capable of securing a stable bonding strength between the piezoelectric vibrating reed 4 and the bumps B, the oscillator 100 having improved yield and stable quality can be provided.

### Electronic Apparatus

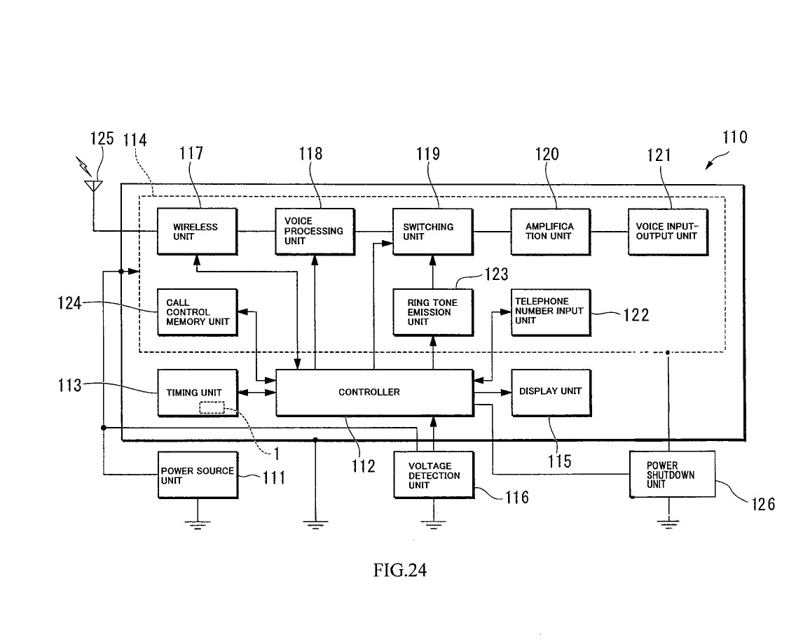

Next, an electronic apparatus according to another embodiment of the invention will be described with reference to FIG. 24. In addition, a portable information device 110 including the piezoelectric vibrator 1 described above will be described as an example of an electronic apparatus.

The portable information device 110 according to the present embodiment is represented by a mobile phone, for example, and has been developed and improved from a wristwatch in the related art. The portable information device 110 is similar to a wristwatch in external appearance, and a liquid crystal display is disposed in a portion equivalent to a dial pad so that a current time and the like can be displayed on this screen. Moreover, when it is used as a communication apparatus, it is possible to remove it from the wrist and to perform the same communication as a mobile phone in the related art with a speaker and a microphone built in an inner portion of the band. However, the portable information device 110 is very small and light compared with a mobile phone in the related art.

Next, the configuration of the portable information device 110 according to the present embodiment will be described. As shown in FIG. 24, the portable information device 110 includes the piezoelectric vibrator 1 and a power supply section 111 for supplying power. The power supply section 111 is formed of a lithium secondary battery, for example. A control section 112 which performs various kinds of control, a clock section 113 which performs counting of time and the like, a communication section 114 which performs communication with the outside, a display section 115 which displays various kinds of information, and a voltage detecting section 116 which detects the voltage of each functional section are connected in parallel to the power supply section 111. In addition, the power supply section 111 supplies power to each functional section.

The control section 112 controls an operation of the entire system. For example, the control section 112 controls each functional section to transmit and receive the audio data or to measure or display a current time. In addition, the control section 112 includes a ROM in which a program is written in advance, a CPU which reads and executes a program written in the ROM, a RAM used as a work area of the CPU, and the like.

The clock section 113 includes an integrated circuit, which has an oscillation circuit, a register circuit, a counter circuit, and an interface circuit therein, and the piezoelectric vibrator 1. When a voltage is applied to the piezoelectric vibrator 1, the piezoelectric vibrating reed 4 vibrates, and this vibration is converted into an electrical signal due to the piezoelectric property of crystal and is then input to the oscillation circuit as the electrical signal. The output of the oscillation circuit is binarized to be counted by the register circuit and the counter circuit. Then, a signal is transmitted to or received from the control section 112 through the interface circuit, and current time, current date, calendar information, and the like are displayed on the display section 115.

The communication section 114 has the same function as a mobile phone in the related art, and includes a wireless section 117, an audio processing section 118, a switching section 119, an amplifier section 120, an audio input/output section 121, a telephone number input section 122, a ring tone generating section 123, and a call control memory section 124.

The wireless section 117 transmits/receives various kinds of data, such as audio data, to/from the base station through an antenna 125. The audio processing section 118 encodes and decodes an audio signal input from the wireless section 117 or the amplifier section 120. The amplifier section 120 amplifies a signal input from the audio processing section 118 or the audio input/output section 121 up to a predetermined level. The audio input/output section 121 is formed by a speaker, a microphone, and the like, and amplifies a ring tone or incoming sound to a louder volume or collects the sound.

In addition, the ring tone generating section 123 generates a ring tone in response to a call from the base station. The switching section 119 switches the amplifier section 120, which is connected to the audio processing section 118, to the ring tone generating section 123 only when a call arrives, so that the ring tone generated in the ring tone generating section 123 is output to the audio input/output section 121 through the amplifier section 120.

In addition, the call control memory section 124 stores a program related to incoming and outgoing call control for communications. Moreover, the telephone number input section 122 includes, for example, numeric keys from 0 to 9 and other keys. The user inputs a telephone number of a communication destination by pressing these numeric keys and the like.

The voltage detecting section 116 detects a voltage drop when a voltage, which is applied from the power supply section 111 to each functional section, such as the control section 112, drops below the predetermined value, and notifies the control section 112 of the detection. In this case, the predetermined voltage value is a value which is set beforehand as a lowest voltage necessary to operate the communication section 114 stably. For example, it is about 3 V. When the voltage drop is notified from the voltage detecting section 116, the control section 112 disables the operation of the wireless section 117, the audio processing section 118, the switching section 119, and the ring tone generating section 123. In particular, the operation of the wireless section 117 that consumes a large amount of power should be necessarily stopped. In addition, a message informing that the communication section 114 is not available due to insufficient battery power is displayed on the display section 115.

That is, it is possible to disable the operation of the communication section 114 and display the notice on the display section 115 by the voltage detecting section 116 and the control section 112. This message may be a character message. Or as a more intuitive indication, a cross mark (X) may be displayed on a telephone icon displayed at the top of the display screen of the display section 115.

In addition, the function of the communication section 114 can be more reliably stopped by providing a power shutdown section 126 capable of selectively shutting down the power of a section related to the function of the communication section 114.

As described above, since the portable information device 110 according to the present embodiment includes the piezoelectric vibrator 1 capable of securing a stable bonding strength between the piezoelectric vibrating reed 4 and the bumps B, the portable information device 110 having improved yield and stable quality can be provided.

### Radio-Controlled Timepiece

Next, a radio-controlled timepiece according to still another embodiment of the invention will be described with reference to FIG. 25.

As shown in FIG. 25, a radio-controlled timepiece 130 according to the present embodiment includes the piezoelectric vibrators 1 electrically connected to a filter section 131. The radio-controlled timepiece 130 is a clock with a function of receiving a standard radio wave including the clock information, automatically changing it to the correct time, and displaying the correct time.

In Japan, there are transmission centers (transmission stations) that transmit a standard radio wave in Fukushima Prefecture (40 kHz) and Saga Prefecture (60 kHz), and each center transmits the standard radio wave. A long wave with a frequency of, for example, 40 kHz or 60 kHz has both a characteristic of propagating along the land surface and a characteristic of propagating while being reflected between the ionospheric layer and the land surface, and therefore has a propagation range wide enough to cover the entire area in Japan through the two transmission centers.

Hereinafter, the functional configuration of the radio-controlled timepiece 130 will be described in detail.

An antenna 132 receives a long standard radio wave with a frequency of 40 kHz or 60 kHz. The long standard radio wave is obtained by performing AM modulation of the time information, which is called a time code, using a carrier wave with a frequency of 40 kHz or 60 kHz. The received long standard wave is amplified by an amplifier 133 and is then filtered and synchronized by the filter section 131 having the plurality of piezoelectric vibrators 1.

In the present embodiment, the piezoelectric vibrators 1 include crystal vibrator sections 138 and 139 having resonance frequencies of 40 kHz and 60 kHz, respectively, which are the same frequencies as the carrier frequency.

In addition, the filtered signal with a predetermined frequency is detected and demodulated by a detection and rectification circuit 134. Then, the time code is extracted by a waveform shaping circuit 135 and counted by the CPU 136. The CPU 136 reads the information including the current year, the total number of days, the day of the week, the time, and the like. The read information is reflected on an RTC 137, and the correct time information is displayed.

Because the carrier wave is 40 kHz or 60 kHz, a vibrator having the tuning fork structure described above is suitable for the crystal vibrator sections 138 and 139.

Moreover, although the above explanation has been given for the case in Japan, the frequency of a long standard wave is different in other countries. For example, a standard wave of 77.5 kHz is used in Germany. Therefore, when the radio-controlled timepiece 130 which is also operable in other countries is assembled in a portable device, the piezoelectric vibrator 1 corresponding to frequencies different from the frequencies used in Japan is necessary.

As described above, since the radio-controlled timepiece 130 according to the present embodiment includes the piezoelectric vibrator 1 capable of securing a stable bonding strength between the piezoelectric vibrating reed 4 and the bumps B, the radio-controlled timepiece 130 having improved yield and stable quality can be provided.

While the embodiments of the invention have been described in detail with reference to the accompanying drawings, the specific configuration is not limited to the above-described embodiments, and various changes may be made in design without departing from the spirit of the invention.

For example, although in the above-described embodiment, the through-holes 30 and 31 have a conical shape having a tapered sectional shape, they may have an approximately cylindrical shape having a straight shape rather than the tapered sectional shape.

In addition, in the above-described embodiment, it is preferable that the core portion 7 has approximately the same thermal expansion coefficient as the base substrate 2 (base substrate wafer 40) and the cylindrical member 6.

In this case, when baking is performed, the three members, namely the base substrate wafer 40, the cylindrical member 6, and the core portion 7 will experience the same thermal expansion. Therefore, there will be no problems resulting from the different thermal expansion coefficients, for example, a case where excessive pressure is applied to the base substrate wafer 40 or the cylindrical member 6, thus forming cracks or the like, and a case where a gap is formed between the cylindrical member 6 and the through-holes 30 and 31 or between the cylindrical member 6 and the core portion 7. Therefore, it is possible to form the penetration electrodes having higher quality, and accordingly, to achieve a further improvement in the quality of the piezoelectric vibrator 1.

For example, although the above-described embodiments have been described by way of an example of the grooved piezoelectric vibrating reed 4 in which the groove portions 18 are formed on both surfaces of the vibrating arms 10 and 11 as an example of the piezoelectric vibrating reed 4, the piezoelectric vibrating reed 4 may be a type of piezoelectric vibrating reed without the groove portions 18. However, since the field efficiency between the pair of the excitation electrodes 15 when a predetermined voltage is applied to the pair of excitation electrodes 15 can be increased by forming the groove portions 18, it is possible to suppress the vibration loss further and to improve the vibration properties much more. That is to say, it is possible to decrease the CI value (crystal impedance) further and to improve the performance of the piezoelectric vibrating reed 4 further. In this respect, it is preferable to form the groove portions 18.

In addition, although the embodiment has been described by way of an example of a tuning-fork type piezoelectric vibrating reed 4, the piezoelectric vibrating reed of the present invention is not limited to the tuning-fork type piezoelectric vibrating reed but may be a thickness-shear type piezoelectric vibrating reed, for example.

Moreover, although in the above-described embodiments, the base substrate 2 and the lid substrate 3 are anodically bonded by the bonding film 35, the bonding method is not limited to the anodic bonding. However, anodic bonding is preferable because the anodic bonding can tightly bond both substrates 2 and 3.

What is claimed is:

1. A method for producing piezoelectric vibrators, comprising:
(a) defining a plurality of first substrates on a first wafer and a plurality of second substrates on a second wafer;
(b) forming conductive patterns on a respective at least some of the first substrates;
(c) forming a bump, made of a metal, in electrical contact with a respective at least some of the conductive patterns;
(d) forming a plurality of piezoelectric vibrating reeds each having a pair of mount electrodes each coated at least in part with a bonding film made of the same metal as the bump;
(e) mounting the piezoelectric vibrating reed in electrical contact with the conductive patterns on respective at least some of the first substrates in such a manner that the bonding film and the bump are fused together;
(f) layering the first and second wafers such that at least some of the first substrates substantially coincide respectively with at least some of the corresponding second substrates, wherein the piezoelectric vibrating reed is secured in a cavity formed between a respective pairs of at least some of coinciding first and second substrates;
(g) hermetically bonding the first and second substrates of at least some of the respective pairs;
(h) cutting off respective at least some of the hermetically bonded pairs from the first and second wafers.

2. The method according to claim 1, wherein forming a bump in electrical contact with a respective at least some of the conductive patters comprises forming a second bonding film at least in part on the respective at least some of the conductive patterns.

3. The method according to claim 2, wherein forming a bump on a respective at least some of the conductive patters further comprises fusing the bump and the second bonding film together.

4. The method according to claim 1, wherein hermetically bonding the first and second substrates comprises anodically bonding the first and second substrates.

5. The method according to claim 1, further comprising press-forming a pair of non-penetrating holes at once in respective at least some of the first substrates.

6. The method according to claim 5, further comprising grinding a surface of the first wafer to make the non-penetrating holes through-holes.

7. The method according to claim 6, further comprising filling a respective at least some of the through-holes with filler.

8. The method according to claim 7, wherein filling a respective at least some of the through-holes comprises filling the at least some of the through-holes with a conductive member inserted therein.

9. The method according to claim 1, wherein the bump and the bonding film are made of gold.

10. The method according to claim 1, wherein the bonding film has a thickness in a range of about 500 to about 600 Å.

11. The method according to claim 2, wherein the second bonding film has a thickness in a range of about 1000 to about 1500 Å.

12. A piezoelectric vibrating reed comprising:
a base and vibrating arms connected to the base;
mount electrodes formed at least in part on the base; and
a bonding film made of gold formed at least in part on the respective mount electrode.

13. A piezoelectric vibrator comprising:
a hermetically closed casing comprising first and second substrates with a cavity inside, wherein the first substrate is formed with conductive patterns on each of which a bump made of gold is formed in electrical contact with the conductive pattern; and
the piezoelectric vibrating reed of claim 12 secured inside the cavity and electrically connected via the mount electrodes to the conductive pattern in such a manner that the bonding films and the bumps are fused together.

14. The piezoelectric vibrator according to claim 13, wherein the conductive patters are each formed with a second bonding film, and bumps and the second bonding films are fused together.

15. The piezoelectric vibrator according to claim 12, wherein the bonding film has a thickness in a range of about 500 to about 600 Å.

16. The piezoelectric vibrator according to claim 14, wherein the second bonding film has a thickness in a range of about 1000 to about 1500 Å.

17. An oscillator comprising the piezoelectric vibrator defined in claim 13.

18. An electronic device comprising the piezoelectric vibrator defined in claim 13.

19. The electronic device according to claim 18, wherein the electronic device is a radio-controlled timepiece.
